(19) United States
(12) Patent Application Publication
(10) Pub. No.: US 2014/0145510 A1
(43) Pub. Date: May 29, 2014

(54) POWER SUPPLY DEVICE OF A DISCHARGE CIRCUIT SEQUENCE

(71) Applicant: THALES, Neuilly Sur Seine (FR)

(72) Inventors: Laurent Pubert, Cholet (FR); Sylvain Gavaud, Cholet (FR)

(21) Appl. No.: 14/092,080

(22) Filed: Nov. 27, 2013

(30) Foreign Application Priority Data
Nov. 28, 2012 (FR) FR1203220

(51) Int. Cl. H03K 17/28

(52) U.S. Cl. CPC H03K 17/28
USPC 307/81

(57) ABSTRACT

The power supply device (10) includes:
a main command input (40) for the activation/deactivation of the power supply device; a power supply unit (22) that includes a discharge circuit (24) connecting the power output (V2) to a reference potential by means of a controlled switch (32); and a control circuit (26) of the controlled switch (32) of the discharge circuit (24).
   This control circuit (26) includes:
a charge/discharge timing circuit (62) characterised by a relaxation time,
a logic circuit (60; 160), one input of which is connected to the main command input (40) of the power supply device, and the other input is connected to the output of the timing circuit (62), and
the output is connected for its control to the controlled switch (32).
   The first logic circuit (60) is adapted to that the controlled switch (32), is only turned on when the two following conditions are met:
no activation signal is present on the main control input (40); and
the output of the timing circuit (62) has reached a value greater than or equal to that provided at the end of the relaxation time.

This invention concerns a power supply device including:

a main command input for the activation/deactivation of the power supply device;

a power supply unit, including:

a command input for the activation/deactivation of the power supply unit depending on the signal originating from the main command input;

a power output adapted to provide a supply current when the power supply unit is activated;

a discharge circuit connecting the power output to a reference potential via a controlled switch;

a control circuit for the controlled switch of the discharge circuit.

Electronic equipment customarily includes a power supply device and a charge supplied by the power supply device, with the charge ensuring the functioning of the electronic equipment.

In the known art, outside of times in which the electronic equipment is used, the power supply device is deactivated. Because of the power supply structure, the voltage at the output only decreases very slowly following the deactivation of the power supply. This residual voltage may be harmful for the load that continues to be supplied. This is the case when the load is a liquid crystal matrix commonly known as an LCD matrix.

In order to avoid output voltage persisting when the power supply is deactivated, a first solution consists of providing a resistive load at the output of the power supply, which resistive load ensures rapid discharge of the power supply after deactivation. This solution, however, has the disadvantage of maintaining a supplemental resistive load on the feed line, thus increasing the overall power consumption of the electrical circuit.

Another solution is to provide a discharge circuit or shunt that earths the supply output. This discharge circuit is controlled with a signal other than the power supply deactivation signal in order to turn the shunt on only after the power supply has been deactivated. Thus, it is worthwhile to provide a power supply sequencer that generates a signal activating/deactivating the power supply and simultaneously generates a signal activating/deactivating the discharge shunt.

This solution is relatively expensive because it needs the presence of a sequencer suitable to provide both control signals.

The invention seeks to provide a power supply device having a simple structure, whilst allowing for a reduction in the output voltage of the power supply after it is deactivated.

To this end, the invention concerns a power supply device of the aforementioned type, characterised in that the control circuit includes:

a first charge/discharge timing circuit, characterised in that it has a relaxation time during the transitory period in the presence/absence of a power supply signal;

a first logic circuit, in which:

one input is connected to the main control input of the power supply device;

the other input is connected to the output of the first timing circuit; and

the output is connected for its control to the controlled switch;

whereby the first logic circuit is adapted to that the controlled switch, is only turned on when the two following conditions are met:

no activation signal is present on the main control input; and

the output of the first timing circuit has reached a value greater than or equal to that provided at the end of the relaxation time of the first timing circuit.

According to specific embodiments, the power supply device includes one or more of the following features:

the first logic circuit is an OR gate;

the first logic circuit is an AND gate having two inverting inputs;

the first timing circuit includes a capacitor connected between the input of the first logic circuit and a reference potential and a resistor connected between the same input of the first logic circuit and the control input for the activation/deactivation of the power supply unit;

the device includes:

a second charge/discharge timing circuit, characterised in that it has a relaxation time during the transitory period in the presence/absence of a power supply signal;

a second logic circuit, in which:

one input is connected to the main control input of the power supply device;

the other input is connected to the output of the second timing circuit; and

the output is connected to the command input for the activation/deactivation of the power supply unit;

whereby the second logic circuit is adapted to that the control input of the power supply unit only receives an activation signal only when the two following conditions are met:

an activation signal is present on the main control input; and

the output of the second timing circuit has reached a value greater than or equal to that provided at the end of the relaxation time of the second timing circuit.

the second logic circuit is a gate;

the second logic circuit is an AND gate having an inverting input;

the timing circuit includes a capacitor connected between the input of the second logic circuit and a reference potential and a resistor connected between the same input of the logic circuit and the output of the first logic circuit;

the discharge circuit includes a resistor connected in series with the controlled switch;

said device includes an inverting gate arranged between the output of the first logic circuit and the controlled switch.

The invention will be more easily understood based on the following description, provided by way of example only, and by reference to the drawings appended hereto, in which:

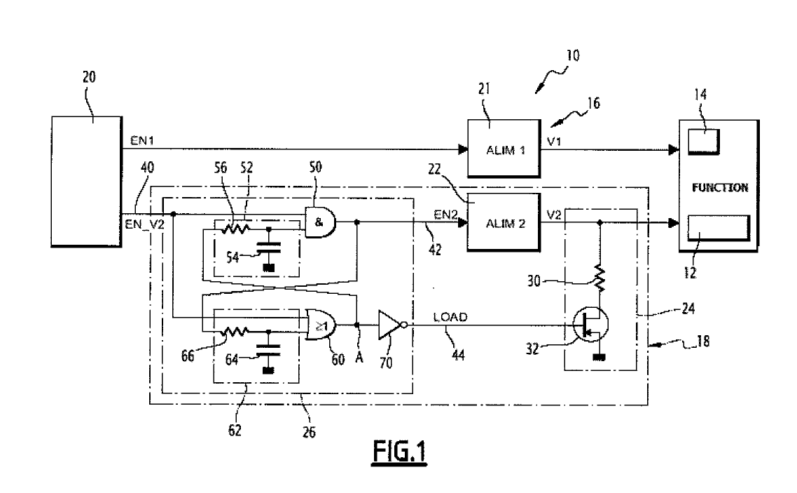

FIG. 1 is a partially schematic representation of an electronic equipment having a power supply according to the invention;

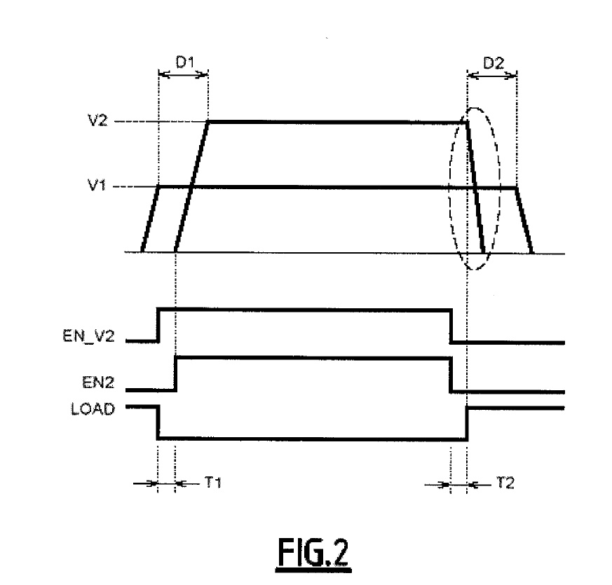

FIG. 2 is a time chart illustrating the conditions at different points of the circuit of FIG. 1; and

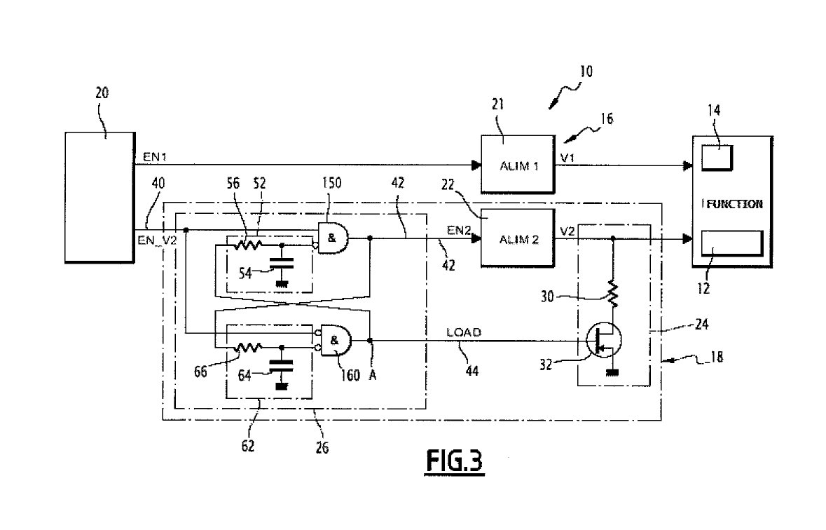

FIG. 3 is a view identical to that of FIG. 1, of an another embodiment of an electronic equipment having a power supply device according to the invention.

The electronic equipment 10 shown in FIG. 1 is, for example, an LCD screen. This screen includes an LCD matrix or panel 12, as well as a circuit 14 controlling the LCD panel.

For its power supply, the control circuit 14 is connected to a first power supply device 16, whilst the LCD matrix 12 is connected to a second, different power supply device 18. The power supply devices 16 and 18 are suitable to provide a respective output voltage when activated that is equal to V1 and V2, adapted to the circuit supplied by them.

The LCD screen 10 lastly includes a synchroniser 20 adapted to control the power supply devices 16 and 18, and, in particular, adapted to provide a signal EN1 for the activation/deactivation of the power supply device 16 and a signal EN_V2 for the activation/deactivation of the pxower supply device 18.

When the LCD screen is switched on, the synchroniser 20 is adapted first to activate the power supply device 16, and then, only a few moments later, to activate the power supply device 18 of the LCD matrix 12, such that the voltage V1 is established before the voltage V2, as shown in FIG. 2. The time lag is indicated by D1.

Likewise, when the LCD screen is turned off, the synchroniser 20 is adapted to give the command to deactivate the power supply device 18 before the deactivation of the power supply device 16, with a time lag designated as D2 that can be seen in FIG. 2.

The power supply devices 16 and 18 are activated when the activation/deactivation signals, EN1 and EN_V2 respectively, are equal to 1, and deactivated when the activation/deactivation signals EN1 and EN_V2 are equal to 0.

The power supply device 16 includes a power supply unit 21 that receives the control signal EN1 directly at the input, and provides, at the output, the supply current applied directly to the control circuit 14.

The power supply unit 21 is, for example, a regulated linear power supply.

The power supply 18 includes a power supply unit 22 constituted by, for example, a Boost-type switch-mode power supply, known as a ‘step-up DC/DC converter’, The output of the power supply unit 22 forms the output of the power supply device 18. Thus, the input of the panel 12 is directly connected at the output of the power supply unit 22, without a resistance connected in series between them.

The power supply device 18 further includes a shunt or discharge circuit 24 for the supply output of the supply unit 22 and a control circuit 26 for the discharge circuit 24 based on the same activation/deactivation signal of the power supply device 18 that is designated EN_V2. According to the invention, the control circuit 26 has no programmable calculators, and only includes passive logic elements and discrete components.

The discharge circuit 24 has, connected in series between the output of the power supply unit 22 that forms the output of the power supply device 18 and the earth, a discharge resistor 30 and a MOSFET transistor 32 adapted to ensure selective earthing of the resistor 30. The control gate of the transistor 32 is connected to a control output of the control circuit 26, the control signal of which is designated LOAD.

The control circuit 26 includes a single input 40 that is connected to the output of the sequencer 20 to receive the activation/deactivation signal EN_V2. It includes an output 42 connected to the control input of the power supply unit 22 that is suited to transmit to the power supply unit an activation/deactivation signal designated EN2. The second output 44 of the control circuit is adapted to provide the command LOAD for the control of the transistor 32.

The power supply unit 22 is suited to be activated when the signal EN2 is equal to 1, and deactivated when the signal EN2 is equal to 0.

The input 40 of the control circuit 26 is connected to a first output of an AND gate 50, the output of which constitutes the output 42 of the control circuit 26. The other input of the AND gate 50 is connected to an RC timing circuit 52. The circuit 52 includes a capacitor 54 that is connected between the second input of the AND gate and the earth, as well as a charge/discharge resistor 56, one of the terminals of which is connected between the second input of the AND gate 50 and the capacitor 54. In transitional mode, the timing circuit has a relaxation time defined by the values of the resistor and the capacitor in the event that the power supply is cut off or the power supply is started.

The control circuit 26 includes an OR gate 60, a first input of which is directly connected to the input 40, and the second input of which is connected to an RC timing circuit 62.

This circuit 62, like the circuit 52, includes a capacitor 64 that is arrange between the earth and the second input of the OR circuit 60, as well as a charge/discharge resistor 66, one terminal of which is connected between the capacitor 64 and the second input of the OR gate 60.

The output of the OR circuit 60 is connected to the control gate of the transistor 32 via a NO gate 70 that forms an inverter. The output of the inverter 70 constitutes the output 44 of the control circuit 26.

The second terminals of the resistors 56, 66 are connected respectively to the output of the OR gate 60 and to the output of the AND gate 50.

The operation of the electronic equipment will be described below. The various states of the control circuit 26 are shown below in the truth table 1, and will be described in detail in the description below. The value A corresponds to the value of the output of the OR gate 60.

TRUTH TABLE 1

| EN_V2 | A | EN2 | LOAD | Comment |
|---|---|---|---|---|
| 0 | 0 | 0 | 1 | The voltage V2 is discharged via R₃₀ |
| 1 | 1 | 0 | 0 | The shunt R₃₀ of the voltage V2 is |
| | | | | released |
| 1 | 1 | 1 | 0 | The voltage V2 is active |
| 0 | 1 | 0 | 0 | The voltage V2 is not active |
| 0 | 0 | 0 | 1 | The voltage V2 is discharged via R₃₀ |

When the equipment is turned on, as shown in FIG. 2, the sequencer 20 first establishes the voltage V1, and the signal EN_V2 then becomes 1.

Whilst the signal EN_V2 is equal to 0, with the capacitors 54 and 64 being discharged, the power supply unit 22 is deactivated, and the signal EN2 is nil while the discharge circuit 24 is activated, with the signal LOAD being equal to 1.

When the signal EN_V2 becomes 1 following the establishment of the voltage V1, the output of the OR gate 60 becomes 1, causing the transistor 32 to be blocked, and the signal LOAD takes on the value 0. Thus, the output of the power supply unit 22 is first disconnected from the earth.

Because the output of the OR gate 60 is equal to 1, the capacitor 54 progressively charges via the resistor 56. When the voltage at the terminals of the capacitor 54 becomes greater than a predetermined threshold of the AND gate 50, the AND gate 50 becomes 1, with the two inputs of the AND gate 50 being equal to 1. This time period corresponds to the relaxation time of the circuit, and is designated T1 in FIG. 2. When the signal EN2 is equal to 1, the power supply unit 22 is activated, and its output voltage V2 increases to reach the voltage V2 at the end of the time period D1. Likewise, the capacitor 64 charges via the resistor 66 to apply a value of 1 to the input of the OR gate 60.

To turn off the display screen, the sequencer 20 first changes the signal EN_V2 to 0, such that the signal EN2 at the output of the AND gate 50 immediately returns to nil, resulting in the deactivation of the power supply unit 22.

When the capacitor 64 is charged, because it is supplied with power for the entire preceding period, during which the signal EN2 was equal t 1, the output of the OR gate 60 temporarily remains at 1, even when the signal EN_V2 is equal to 0, thus keeping the transistor 32 in the blocked state, with the control signal LOAD being equal to 0.

The capacitor 64 is then progressively discharged via the resistor 66, and the value EN2 is nil.

When the capacitor 64 is sufficiently discharged and at a voltage that is below a predetermined voltage of the OR gate 60, the two inputs of the OR gate 60 are equal to 0, thus toggling the output A to 0, which causes the transistor 32 to be toggled to on; the value LOAD is equal to 1.

Thus, after a period of time T2 after the toggling of the signal EN_V2 to 0, corresponding to the relaxation time of the circuit 62, the output voltage of the power supply unit 22 falls to 0 due to the circulation of current through the discharge resistor 30.

After a duration D2, the power supply unit 21 is controlled so as to be deactivated, with the value EN1 being set to 0 by the sequencer.

It is conceivable that, with such a power supply device 18, it would be possible to use a single activation/deactivation signal EN_V2, and based on simple logic circuits and passive RC circuits, to ensure synchronicity between the activation/deactivation of the power supply unit 22 and earthing, via a discharge resistor 30, of the output of the power supply unit.

Thus, this solution is particularly economical and reliable.

In one variant, the RC timing circuits are replaced by RL or RLC circuits.

FIG. 3 shows an alternative embodiment of the power supply device 10. In this figure, those elements that are identical or equivalent to those of FIG. 1 have the same reference numbers.

In this embodiment, the inverter 70 is omitted, and the AND gate 50 is replaced by an AND gate 150, the second input of which, which is connected to the delay circuit 52, is acts as an inverter. Likewise, the OR gate 60 is replaced by an AND gate 160, the two inputs of which are inverters.

Truth Table 2 of the control circuit 26 is shown below. The sequencing of the signals EN_V2, EN2, and LOAD is identical to that of the first embodiment, with only the state at point A being the opposite.

TRUTH TABLE 2

| EN_V2 | A | EN2 | LOAD | Comment |
|---|---|---|---|---|
| 0 | 1 | 0 | 1 | The voltage V2 is discharged via R₃₀ |
| 1 | 0 | 0 | 0 | The shunt R₃₀ of the voltage V2 is |
| | | | | released |
| 1 | 0 | 1 | 0 | The voltage V2 is active |
| 0 | 0 | 0 | 0 | The voltage V2 is not active |
| 0 | 1 | 0 | 1 | The voltage V2 is discharged via R₃₀ |

This embodiment has the advantage of including one less logic gate, thus further reducing the manufacturing costs.

In this embodiment, the capacitor 54 is initially charged. In fact, when turned on, regardless of the value of the charge of the capacitors 54 and 64, the signal EN_V2 is 0; accordingly, the output of the AND gate 150 is 0. The output of the AND gate 160 may be 0 or 1 (the shunt 24 may be activated). The capacitor 64 is forced to discharge, forcing the value of the output of the AND gate 160 to 1. Accordingly, the capacitor 54 is charged, and the capacitor 64 is discharged. When the signal EN_V2 becomes 1, the switch 32 is immediately opened, and the input to the gate 160 that is connected to the input 40 becomes 1.

The signal EN2 remains at 0 because the input connected to the AND gate 150 remains equal to 1, with the capacitor 54 being charged.

Progressively, the capacitor 54 is discharged via the resistor 56, and the output of the AND gate 160 is at 0. After a sufficient discharge has occurred, the signal EN2 becomes 1.

The capacitor 64 is then progressively charged. After a sufficient charge has occurred, the output of the AND gate 160 is kept at 0.

When the power supply device is deactivated due to EN_V2 passing to 0, the signal EN2 passes to 0, deactivating the power supply unit 22, and the capacitor 64 discharges progressively via the resistor 66 until it reaches a voltage below which the voltage of the output of the gate 160 passes to 1, thus providing delayed activation of the discharge circuit 24.

What is claimed is:

1-10. (canceled)

11. A power supply device, comprising:
a main command input for the activation or deactivation of the power supply device;
a power supply unit, including:
a command input for the activation or deactivation of the power supply unit depending on a signal originating from the main command input; and
a power output adapted to provide a supply current when the power supply unit is activated;
a discharge circuit connecting the power output to a reference potential via a controlled switch; and
a control circuit for the controlled switch of the discharge circuit, the control circuit including:
a first charge or discharge timing circuit having a relaxation time during a transitory period in the presence or absence of a power supply signal; and
a first logic circuit, in which:
one input is connected to the main control input of the power supply device;
another input is connected to the output of the first timing circuit; and
the output is connected for control to the controlled switch;
the first logic circuit being adapted so that the controlled switch is only turned on when the two following conditions are met:
no activation signal is present on the main control input; and
the output of the first timing circuit has reached a value greater than or equal to that provided at an end of the relaxation time of the first timing circuit.

12. The power supply device according to claim 11, wherein the first logic circuit is an OR gate.

13. The power supply device according to claim 11, wherein the first logic circuit is an AND gate having two inverting inputs.

14. The power supply device according to claim 11, wherein the first timing circuit includes a capacitor connected between the other input of the first logic circuit and a reference potential and a resistor connected between the other input of the first logic circuit and the command input for the activation or deactivation of the power supply unit.

15. The power supply device according to claim 11, further comprising:
a second charge or discharge timing circuit having a relaxation time during a transitory period in the presence or absence of a power supply signal; and
a second logic circuit, in which:
one input is connected to the main control input of the power supply device;
another input is connected to the output of the second timing circuit; and
the output is connected to the command input for the activation or deactivation of the power supply unit;
the second logic circuit being adapted so that the command input of the power supply unit receives an activation signal only when the two following conditions are met:
an activation signal is present on the main control input; and
the output of the second timing circuit has reached a value greater than or equal to that provided at an end of the relaxation time of the second timing circuit.

16. The power supply device according to claim 15, wherein the second logic circuit is an AND gate.

17. The power supply device according to claim 15, wherein the second logic circuit is an AND gate having an inverting input.

18. A power supply device according to claim 15, wherein the second timing circuit includes a capacitor connected between the other input of the second logic circuit and a reference potential and a resistor connected between the other input of the second logic circuit and the output of the second logic circuit.

19. The power supply device according to claim 11, wherein the discharge circuit includes a resistor that is connected in series with the controlled switch.

20. The power supply device according to claim 11, further comprising an inverting gate arranged between the output of the first logic circuit and the controlled switch.
